(19) United States
(12) Patent Application Publication
(10) Pub. No.: US 2023/0116153 A1
(43) Pub. Date: Apr. 13, 2023

(54) SYSTEM FOR UNIFORM TEMPERATURE CONTROL OF CLUSTER PLATFORMS

(71) Applicant: Applied Materials, Inc., Santa Clara, CA (US)

(72) Inventors: Lakshmikanth Krishnamurthy SHIRAHATTI, Bangalore (IN); Kirankumar Neelasandra SAVANDAIAH, Bangalore (IN); Prashant A. DESAI, Bangalore (IN); Thomas BREZOCZKY, Los Gatos, CA (US)

(21) Appl. No.: 17/851,638

(22) Filed: Jun. 28, 2022

Related U.S. Application Data
(60) Provisional application No. 63/254,463, filed on Oct. 11, 2021.

(51) Int. Cl. H01L 21/67

(52) U.S. Cl. CPC H01L 21/67109; H01L 21/67023

(57) ABSTRACT

Aspects of the disclosure provided herein generally relate to a fluid flow network configured to cool subsystems of a substrate processing system. Aspects of the disclosure provide a fluid flow network and method that adjusts the flow of the cooling fluid through each subsystem of the substrate processing system. The methods described herein can include maintaining a flow rate of the cooling fluid through each subsystem over a range of cooling fluid pressures. The methods described herein can further include configuring the fluid flow network to equalize a flow rate of the cooling fluid through similar subsystems such that the flow rate through each subsystem is similar without adjustment.

### CROSS-REFERENCE TO RELATED APPLICATIONS

This application claims priority to U.S. Provisional Application Ser. No. 63/254,463 filed Oct. 11, 2021, which is herein incorporated by reference in its entirety.

### FIELD

The present disclosure relates to an apparatus and method of processing substrates in a sub-atmospheric pressure environment. More particularly, the present disclosure relates to cooling a substrate processing system suitable for semiconductor processing.

### BACKGROUND

Deposition and dry etch processes are used to form layers on, and remove all or a portion of one or more layers from, a substrate. For example, it is known to deposit thin metal and dielectric films on substrates, such as directly on a semiconductor substrate or on film layers already formed thereon, using a sputtering process, also known as physical vapor deposition (PVD). Other methods of forming a thin film on a substrate are chemical vapor deposition (CVD) and plasma enhanced CVD (PECVD). Dry etching is commonly used in semiconductor processing to form features in a substrate, or in one or more thin films on the substrate by a reactive ion etch process.

Many thin film deposition and etch processes used in semiconductor and flat panel display production employ substrate processing chambers that are attached to a mainframe of a cluster tool, referred to as a substrate processing system, wherein one or more substrates are loaded into a dedicated processing chamber (e.g., a vacuum chamber) having dedicated hardware therein to support the substrate during a process performed thereon. Maintaining a uniform process temperature is critical for process requirements, safety, and component life. During the thin film deposition and etch processes, large amounts of heat are generated. Components placed in close proximity to a processing region of the chamber can be affected by the heat generated during processing, which can generate extreme temperatures if not adequately controlled. Uncontrolled high temperatures can degrade components over extended periods of time.

Operating temperatures in multi-station processing systems may vary from chamber to chamber (e.g., process station to process station). Conventional cooling methods and systems flow cooling fluid to each process station. However, the cooling fluid travels different distances to each station and so the difference in pressures between each station may be high. For example, a process station that is further downstream may have a lower pressure, and thus a lower fluid flow velocity, than a process station that is upstream. The issue of the pressure differential is compounded because each process station has multiple cooling lines to cool different subsystems of the process station. Thus, conventional systems may not cool the different process stations at the same rate and a variation in temperature between each chamber may result.

Cooling each process station of the chamber is challenging because the configuration of the processing system constrains the configuration of the cooling system. For example, a similar flow rate through each processing chamber may be achieved if each cooling line of each process station is routed similarly and has similar properties and dimensions. For example, each cooling line would have the same amount of bends and turns to ensure each cooling line has a similar resistance to flow. Each cooling line would also have to travel a similar distance from a cooling fluid source to each of the process stations. However, the cooling lines cannot be routed symmetrically because components for higher priority subsystems of the processing system obstruct a required routing path. Thus, in conventional cooling systems the processing chambers are located at various distances downstream of the fluid source and a pressure of the cooling fluid through each process station may vary.

Cooling each process station is challenging for several additional reasons. First, even if the configuration of the cooling lines are symmetrical, over time residue may build up on the inside of some cooling lines and restrict the flow of the cooling fluid. Second, the various subsystems of the processing chamber may have different cooling requirements, which may change with a processing chamber procedure or recipe. Third, different cooling fluids requiring different flow rates and having different material properties may be used to cool different subsystems of the processing chamber. Fourth, various structures can attach to the processing chamber and may draw heat away from the processing chamber, further affecting the cooling rate of each process station.

While the conventional cooling system designs are suitable for cooling the processing chamber, such cooling systems can result in chamber matching issues with a large number of hot and cold spots in the processing chamber or result in a non-uniform temperature of the different processing chambers during operations and during bake-out. The temperature variations result in variations in the thin film deposition and etch processes of the processing chamber and an inconsistent product.

Therefore, there is a need for a system and a method of cooling the substrate processing system that solves the problems described above.

### SUMMARY

Embodiments of the present disclosure generally relate to substrate processing systems. In particular, embodiments herein provide systems and methods for cooling subsystems of a substrate processing system.

In one embodiment, a substrate processing system is provided. Generally, the system includes a processing chamber comprising an array of process stations surrounding a central axis and an upper fluid flow network configured to flow an inlet cooling fluid to a first plurality of subsystems of the processing chamber. The upper fluid flow network includes a plurality of cooling assemblies, a supply weldment fluidly connected to an inlet weldment, and at least one collection weldment fluidly connected to an outlet weldment. Each cooling assembly of the plurality of cooling assemblies is associated with a process station of the array of process stations. Each cooling assembly includes an inlet manifold and a plurality of inlet manifold cooling lines, an outlet manifold and a plurality of outlet manifold cooling lines, and an outlet flow restrictor fluidly connected to each subsystem of the first plurality of subsystems and to the outlet manifold. Each inlet manifold cooling line of the plurality of inlet manifold cooling lines fluidly connects the inlet manifold to a subsystem of the first plurality of subsystems. Each outlet manifold cooling line of the plurality of outlet manifold cooling lines fluidly connects each subsystem of the first plurality of subsystems to the outlet manifold. The inlet weldment is fluidly connected to each inlet manifold of each cooling assembly. The outlet weldment is fluidly connected to each outlet manifold of each cooling assembly.

In another embodiment, a substrate processing system is provided. The system includes a cooling system configured to cool a first plurality of subsystems and a second plurality of subsystems of a processing chamber. The cooling system includes a first plurality of cooling lines and a first plurality of flow restrictors. A first subset of the first plurality of cooling lines connects to a first plurality of manifolds. A second subset of the first plurality of cooling lines connects the first plurality of manifolds to the first plurality of subsystems of the processing chamber. A third subset of the first plurality of cooling lines connects the first plurality of subsystems of the processing chamber to a second plurality of manifolds. A fourth subset of the first plurality of cooling lines connects to the second plurality of manifolds. The first plurality of flow restrictors is connected to the second subset or the third subset of the first plurality of cooling lines. Each flow restrictor of the first plurality of flow restrictors connects to a respective cooling line of the second subset or the third subset of the first plurality of cooling lines.

In another embodiment, a method for cooling a substrate processing system is provided. The method includes flowing an inlet cooling fluid through an upper fluid flow network and restricting the flow of the inlet cooling fluid with a plurality of outlet flow restrictors. The upper fluid flow network includes a plurality of cooling assemblies, a supply weldment fluidly connected to an inlet weldment, and at least one collection weldment fluidly connected to an outlet weldment. Each cooling assembly of the plurality of cooling assemblies is associated with a process station of a processing chamber. Each cooling assembly includes an inlet manifold and a plurality of inlet manifold cooling lines and an outlet manifold and a plurality of outlet manifold cooling lines. Each inlet manifold cooling line of the plurality of inlet manifold cooling lines fluidly connects the inlet manifold to a subsystem of a first plurality of subsystems. Each outlet manifold cooling line of the plurality of outlet manifold cooling lines fluidly connects the subsystem of the first plurality of subsystems to the outlet manifold. The inlet weldment is fluidly connected to each inlet manifold of each cooling assembly. The outlet weldment is fluidly connected to each outlet manifold of each cooling assembly. Each outlet flow restrictor of the plurality of outlet flow restrictors is fluidly connected to each subsystem of the first plurality of subsystems and an outlet manifold.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of the scope of the disclosure, as the disclosure may admit to other equally effective embodiments.

FIG. 1 is a plan view of a processing system that includes a processing chamber that includes process stations therein for processing substrates, according to one or more embodiments.

FIG. 2 is an isometric view of a processing chamber with a fluid delivery system, according to one of more embodiments.

FIG. 3A is an isometric view of inlet components of an upper fluid flow network, according to one or more embodiments.

FIG. 3B is an isometric view of outlet components of the upper fluid flow network, according to one or more embodiments.

FIG. 4A is a fluid schematic of an upper fluid flow network for cooling a processing chamber, according to one or more embodiments.

FIG. 4B is a fluid schematic of inlet and outlet manifolds of the upper fluid flow network of FIG. 4A, according to one or more embodiments.

FIG. 5 is a fluid schematic of a lower fluid flow network for cooling a substrate processing system, according to one or more embodiments.

FIGS. 6A and 6B depict example methods of cooling a substrate processing system, according to embodiments described herein.

FIG. 7 depicts an example of a functional block diagram of one example of a controller for cooling a substrate processing system, according to embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

In the following description, numerous specific details are set forth to provide a more thorough understanding of the present disclosure. However, it will be apparent to one of skill in the art that some embodiments of the present disclosure may be practiced without one or more of these specific details. In other instances, well-known features have not been described in order to avoid obscuring one or more embodiments of the present disclosure.

As used herein, the term “about” may refer to a +/−10% variation from the nominal value. It is to be understood that such a variation can be included in any value provided herein.

In view of the above, both a challenge and opportunity exists to improve a cooling process of a processing chamber by controlling a flow rate of a cooling fluid through each subsystem of the processing chamber. Accordingly, a processing chamber is provided with independently controlled flow rates for an improved cooling process and substrate processing performance over time.

Embodiments of the disclosure provided herein generally relate to a fluid flow network configured to cool subsystems of a substrate processing system. Embodiments of the disclosure provide a fluid flow network and method that adjusts the flow of the cooling fluid through each subsystem of the substrate processing system. The methods described herein can include maintaining a flow rate of the cooling fluid through each subsystem over a range of cooling fluid pressures. The methods described herein can further include configuring the fluid flow network to equalize a flow rate of the cooling fluid through similar subsystems such that the flow rate through each subsystem is similar without adjustment.

The methods and apparatuses disclosed herein are useful for cooling subsystems of the processing chamber. A plurality of flow restrictors are disposed throughout the fluid flow network to control a flow rate of a cooling fluid through the subsystems. The plurality of flow restrictors may be positioned at or after one or more of an inlet, an outlet, an input, or an output of each subsystem. The flow restrictors maintain a predetermined flow rate based on the flow restrictor used. Thus, the flow rate through each subsystem can be set independently of the other subsystems, which beneficially allows control of the cooling process for each subsystem of the processing chamber.

### Processing System Configuration Examples

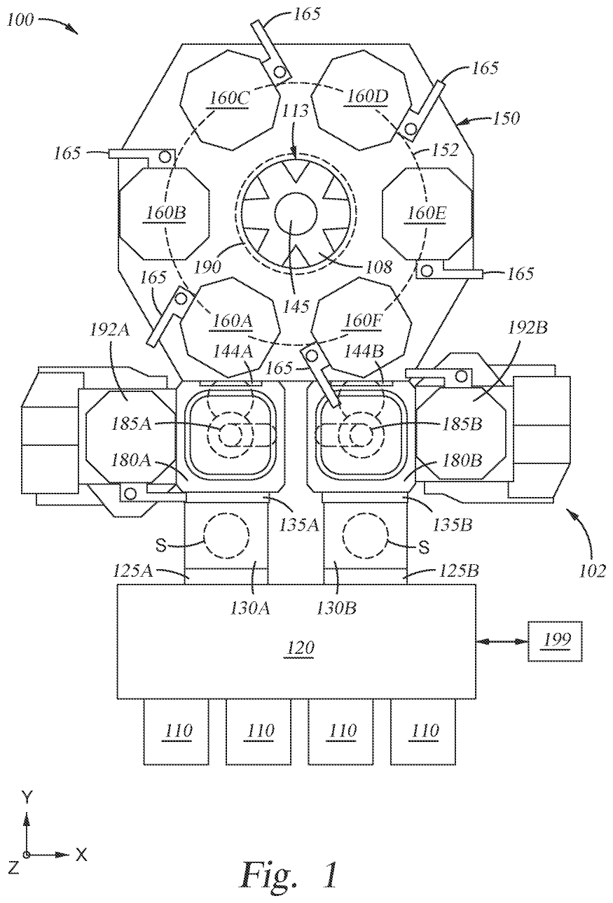

FIG. 1 depicts a plan view of a substrate processing system 100 that includes a processing chamber 150 that includes process stations 160 therein for processing substrates, according to one or more embodiments. The substrate processing system 100 is used to form one or more thin films on the surface of a substrate S and/or, on a layer previously formed or processed on the substrate S. In one embodiment of the disclosure provided herein, a substrate processing system as shown in FIG. 1 includes an atmospheric or ambient pressure substrate input and output handling station also known as a front end 120, the processing chamber 150 having multiple process stations 160 positioned thereon, and at least one intermediary section 102. A substrate is transferred into the intermediary section 102 from the front end 120 or from the processing chamber 150, or transferred from the intermediary section 102 to the front end 120 or to the processing chamber 150. While the disclosure provided herein generally illustrates the processing chamber 150 including six process stations 160A-160F, this configuration is not intended to be limiting as to the scope of the invention provided herein, since the processing chamber 150 might alternatively include two or more process stations 160, such as four or more process stations 160, eight or more process stations 160, ten or more process stations 160, or even 12 or more process stations 160.

The substrate processing system 100 is used to form one or more thin films on the surface of a substrate S and/or, on a layer previously formed or processed on the substrate S. The substrate may be sequentially moved along the circumference of an imaginary circle 152 which intersects a central location of each of the process stations 160, such that a plurality of a first film type layer and a plurality of a second film type layer can be sequentially deposited thereon. Each process station 160A-160F can be independently or similarly configured to enable a deposition process, for example a PVD, CVD, ALD (atomic layer deposition) or other type of deposition process, or an etching process. For example, metal layers may be deposited on a substrate and be composed of a metal, and reactive metal layers may be deposited on a substrate and be composed of a reactive metal (e.g., metal nitride). Each process station 160A-160F includes a vacuum pump 165 configured to evacuate a processing region (not shown) during the deposition processes. The process stations 160A-160F may connect to the vacuum pump 165 through a line that is configured to connect to the vacuum pump 165. By sequentially moving and sequentially processing the substrate in all of process stations 160A-160F, a pure metal/reactive metal/pure metal/reactive metal/pure metal/reactive metal multi-layer film stack can be formed.

A substrate loaded into the processing chamber 150 need not be processed at each process station 160A-160F. For example, each of the process stations 160A-160F can employ the same sputter target material, a number of substrates equal to the number of process stations 160 are loaded into the processing chamber 150, and each substrate is processed in a different one of the process stations 160 for deposition of a same material film layer thereon. Thereafter all of these substrates are removed from the processing chamber 150, and an equal number of substrates are loaded again into the processing chamber 150, and the processing of each of these substrates by a different single one of the process stations 160 is performed. Alternatively, different processes are performed in each adjacent process station 160 arrayed along the circumference of the imaginary circle 152. For example, a first deposition process to deposit a first type of film layer is performed in process stations 160A, 160C and 160E, and a second deposition process to deposit a second type of film layer is performed in process stations 160B, 160D and 160F. However, in this case, an individual substrate is exposed to only two process stations 160, for example a first substrate is exposed to only process stations 160A and 160B, a second substrate is exposed to only process stations 160C and 160D, and a third substrate is exposed to only process stations 160E and 160F. Then the substrates are removed. Likewise, each substrate process in the system can be processed in up to all process stations 160, and the process performed at each process station 160 can be the same or different from one or all of the remaining process stations 160.

The substrate processing system 100 generally includes the processing chamber 150, the intermediary section 102, which is coupled between the processing chamber 150 and the front end 120, and a system controller 199. As shown in FIG. 1, the intermediary section 102 includes a pair of loadlock chambers 130A, 1306 and a pair of intermediate robot chambers 180A, 180B. Each of the loadlock chambers 130A, 130B is separately connected through a respective first valve 125A, 125B, at one side thereof to the front end 120, and through a respective second valve 135A, 135B, to one of the intermediate robot chambers 180A, 180B, respectively. During operation a front end robot (not shown) in the front end 120 moves a substrate therefrom into a loadlock chamber 130A or 130B, or removes a substrate from a loadlock chamber 130A, 130B. Then an intermediary robot 185A, 1856 in one of the associated intermediate robot chambers 180A, 180B connected to an associated one of the loadlock chambers 130A, 130B moves a substrate from the loadlock chamber 130A or loadlock chamber 130B and into the corresponding intermediate robot chamber 180A, 180B. In one aspect, the intermediary section 102 also includes a preclean/degas chamber 192 connected to an intermediate robot chamber 180, for example a preclean/degas chamber 192A connected to intermediate robot chamber 180A and a preclean/degas chamber 192B connected to intermediate robot chamber 180B. A substrate loaded into one of the loadlock chambers 130A, 130B from the front end 120 is moved, by the associated intermediary robot 185A or 185B, from the loadlock chamber 130A or 130B and into the preclean/degas chamber 192A or 192B. In the preclean/degas chambers 192A, 192B, the substrate is heated to volatilize any adsorbed moisture or other volatilizable materials therefrom, and is subjected to a plasma etch process whereby residual contaminant materials thereon are removed. Thereafter, the substrate is moved by the appropriate associated intermediary robot 185A or 185B back into the corresponding intermediate robot chamber 180A or 180B and thence onto a substrate support (not shown) at a process station 160 in the processing chamber 150, here process station 160A or 160F. In some embodiments, once the substrate S is placed on the substrate support, it remains thereon until all processing thereof in the processing chamber 150 is completed.

Here, each of the loadlock chamber 130A and the loadlock chamber 130B is connected to a vacuum pump (not shown), for example a roughing pump, the output of which is connected to an exhaust duct (not shown), to reduce the pressure within the loadlock chamber 130A, 130B to a sub-atmospheric pressure on the order of about 10⁻³ torr. The loadlock chambers 130 may connect to the vacuum pump through a line that is configured to connect to the vacuum pump. Each loadlock chamber 130A or 130B may be connected to a vacuum pump dedicated thereto, or a vacuum pump shared with one or more components within the processing system 100, or to a house exhaust other than a vacuum pump to reduce the pressure therein. In each case, a valve (not shown) can be provided on the loadlock chamber 130A, 130B exhaust to the pump or house exhaust to isolate, or substantially isolate, the pumping outlet of the loadlock chamber 130A, 130B connected to the vacuum pump or house exhaust from the interior volume of the loadlock chamber 130A, 130B when the first valve 125A or 125B respectively is open and the interior of the loadlock chamber 130A, 130B is exposed to atmospheric or ambient pressure conditions.

After the substrate has been processed, for example, in the, preclean/degas chamber 192B, the intermediary robot 185B removes the substrate from the preclean/degas chamber 192B. A process chamber valve 144B, which is disposed between the intermediate robot chamber 180B and the processing chamber 150, is opened to expose a substrate transfer opening formed in a wall of the processing chamber 150, and the intermediary robot 185B moves the substrate through the substrate transfer opening to a process station 160F of the processing chamber 150 where it is received for processing within one or more of the process stations of the processing chamber 150. In the same manner, a substrate can be moved from the front end 120 through the loadlock chamber 130A, to the preclean/degas chamber 192A, and then to the processing chamber 150 through a process chamber valve 144A and a substrate transfer opening (not shown) in the processing chamber 150 wall to be received at process station 160A. Alternatively, the process chamber valves 144A, 144B may be eliminated, and intermediate robot chambers 180A, 180B be in direct uninterrupted fluid communication with the interior of the processing chamber 150

Each of the loadlock chambers 130A, 130B and intermediate robot chambers 180A, 180B are configured to pass substrates from the front end 120 into the processing chamber 150, as well as from the processing chamber 150 and into the front end 120. Thus, with respect to the intermediate robot chamber 180A, to remove a substrate positioned at process station 160A of the processing chamber 150, the process chamber valve 144A is opened, and the intermediary robot 185A removes the substrate from the process station 160A and moves it, through an open second valve 135A connected between the intermediate robot chamber 180A and the loadlock chamber 130A, to place the substrate in the loadlock chamber 130A. The end effector of the intermediary robot 185A on which the substrate was moved is retracted from the loadlock chamber 130A, the second valve 135A thereof is closed, and the interior volume of the loadlock chamber 130A is optionally isolated from the vacuum pump connected thereto. Then the first valve 125A connected to the loadlock chamber 130A is opened, and the front end 120 robot picks up the substrate in the loadlock chamber 130A and moves it to a storage location, such as a cassette or front opening unified pod (FOUP) 110, located within or connected to a sidewall of, the front end 120. In a similar fashion, using the intermediate robot chamber 180B, the intermediary robot 185B, the loadlock chamber 130B and associated valves 135B and 125B thereof, a substrate can be moved from the process station 160F location to the front end 120. During the movement of a substrate from the processing chamber 150 to the front end 120, a different substrate may be located within the preclean/degas chamber 192A, 192B connected to the intermediate robot chamber 180A, 180B through which the substrate being moved to the front end 120 passes. Because each preclean/degas chamber 192A, 192B is isolated from the intermediate robot chamber 180A, 180B to which it is attached by a valve, passage of a different substrate can be undertaken from the processing chamber 150 to the front end 120 without interfering with the processing of a substrate in the respective preclean/degas chambers 192A, 192B.

The system controller 199 controls activities and operating parameters of the automated components found in the processing system 100. In general, the bulk of the movement of a substrate through the processing system is performed using the various automated devices disclosed herein by use of commands sent by the system controller 199. The system controller 199 is a general use computer that is used to control one or more components found in the processing system 100. The system controller 199 is generally designed to facilitate the control and automation of one or more of the processing sequences disclosed herein and typically includes a central processing unit (CPU) (not shown), memory (not shown), and support circuits (or I/O) (not shown). Software instructions and data can be coded and stored within the memory (e.g., non-transitory computer readable medium) for instructing the CPU. A program (or computer instructions) readable by the processing unit within the system controller 199 determines which tasks are performable in the processing system. For example, the non-transitory computer readable medium includes a program which when executed by the processing unit are configured to perform one or more of the methods described herein. Preferably, the program includes code to perform tasks relating to monitoring, execution and control of the movement, support, and/or positioning of a substrate along with the various process recipe tasks and various processing chamber process recipe steps being performed.

A removable central cover 190 (shown as a dashed line to illustrate underlying features) extends over a central opening 113 of the processing chamber 150. The central cover 190 is removable to allow access to the interior of the processing chamber 150 to service a central transfer robot 145 thereof. At least one, and in the case of the processing chamber 150, two substrate transfer openings (not shown) extend inwardly of an outer surface of a side wall and into the transfer region of the processing chamber 150. The transfer openings allow the intermediary robot 185A, 185B, or the central transfer robot 145, to transfer a substrate positioned external to the processing chamber 150 to a position on a substrate support (not shown) that is positioned on a support arm 108 of the central transfer robot 145. Alternately, transfer openings allow the intermediary robot 185A, 1856, or the central transfer robot 145, to remove a substrate from a substrate support (not shown) that is positioned on the support arm 108 of the central transfer robot 145.

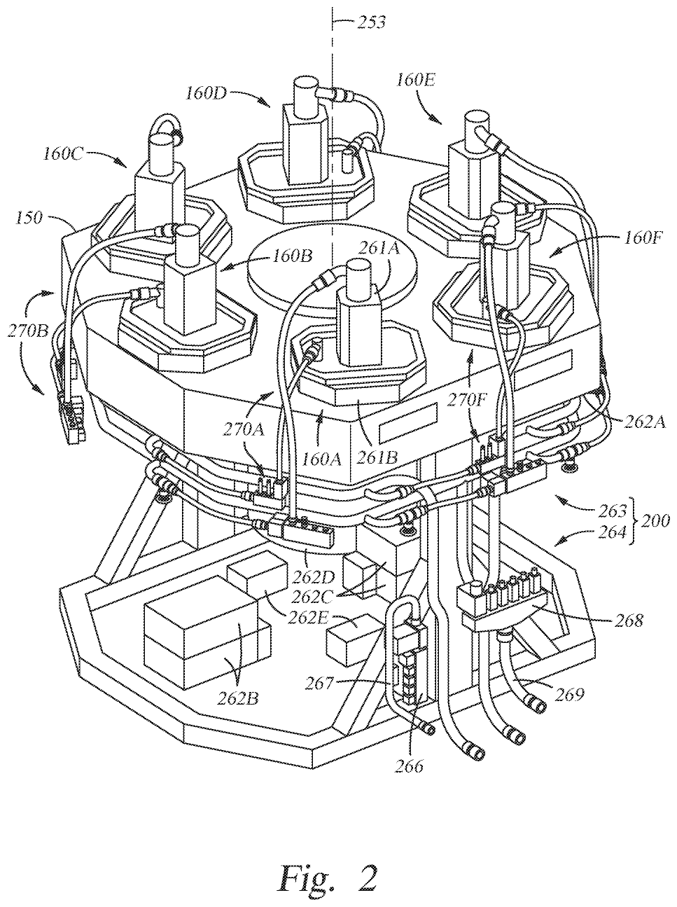

The process stations 160 are arrayed, and are equally and circumferentially spaced from one another, along the imaginary circle 152 centered on and surround a central axis (e.g., a central axis 253 in FIG. 2A) (i.e., parallel to the Z-direction) such that the center of the imaginary circle 152 is coincident with the central axis 253. For example, where the process station 160F is a PVD type of process station 160, the center of the PVD target overlies a portion of the imaginary circle 152, and the centers of the targets of the remaining process stations 160A-160E are equally circumferentially spaced from one another along the imaginary circle 152.

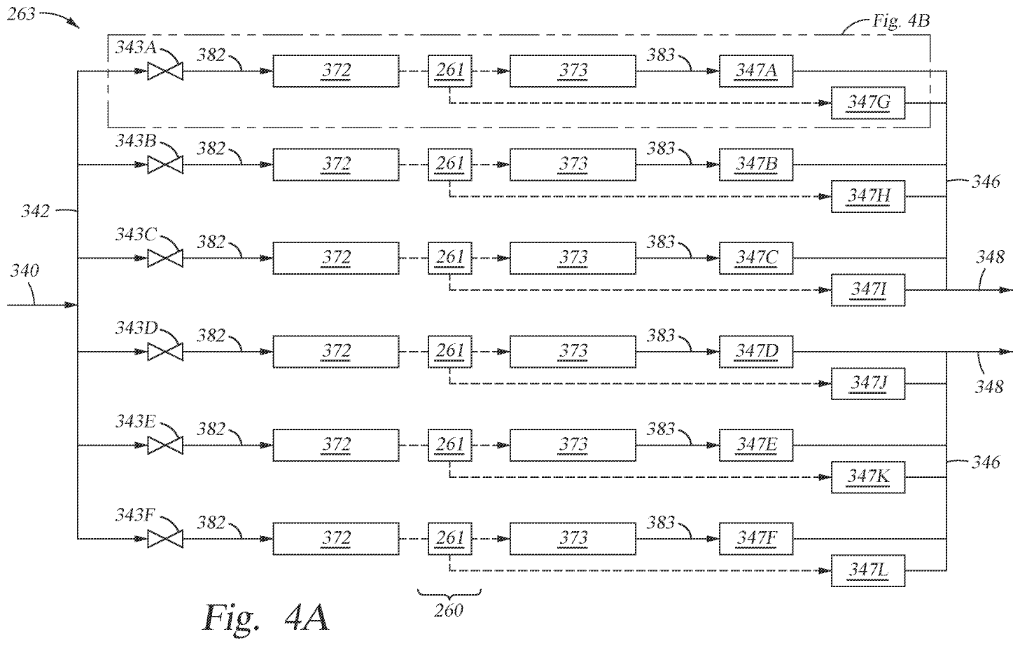

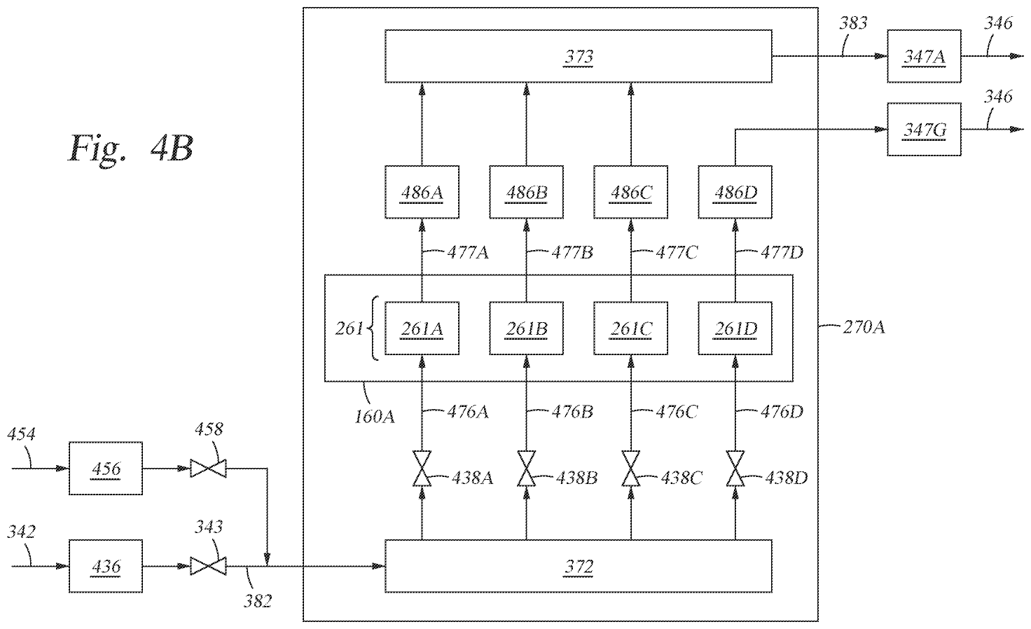

The processing chamber 150 also includes a fluid flow network (not shown) that is used to cool the processing chamber 150 during normal processing, as discussed in relation to FIGS. 2-7. For example, the system 100 includes a cooling assembly (e.g., cooling assemblies 270 as discussed in relation to FIGS. 2, 4A, and 4B) for each process station 160. As previously discussed, each process station 160 may perform a different process than an adjacent process station 160. Thus, the cooling assemblies may cool subsystems of the system 100 at different rates by flowing cooling fluid at different flow rates.

### Fluid Delivery System Configuration Examples

FIG. 2 depicts an isometric view of the processing chamber 150 with a fluid delivery system 200, according to one of more embodiments.

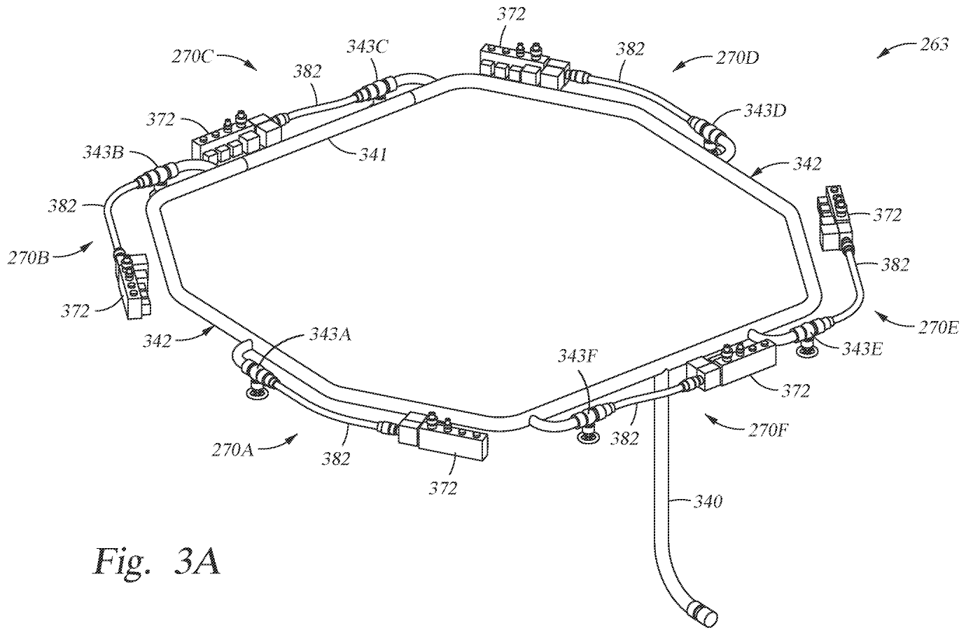

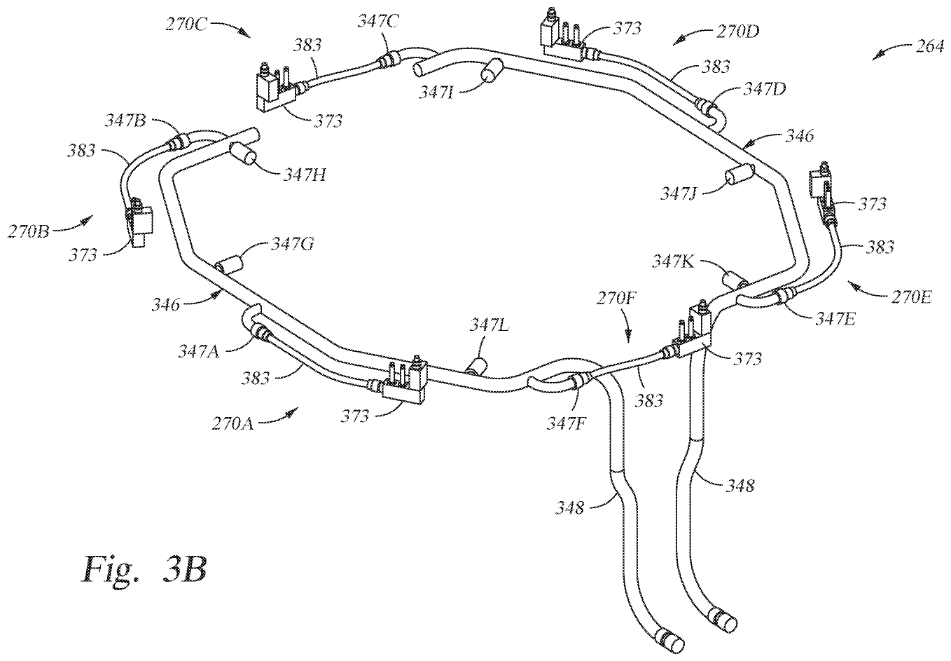

The fluid delivery system 200 includes an upper fluid flow network 263 configured to flow an inlet cooling fluid (not shown) to a first plurality of subsystems 260 of the processing chamber 150. The first plurality of subsystems 260 is not labeled in FIG. 2, but is labeled in FIG. 4A. The upper fluid flow network 263 includes a plurality of cooling assemblies 270, wherein each cooling assembly 270A-270F of the plurality of cooling assemblies 270 is associated with one of the array of process stations 160A-160F, respectively. Although cooling assemblies 270A-270F are shown in FIG. 2, only the cooling assemblies 270A, 270B, and 270F are labeled. Each cooling assembly 270A-270F comprises an inlet manifold 372 and an outlet manifold 373 as discussed in relation to FIGS. 3A and 3B.

The first plurality of subsystems 260 includes an array of subsystems 261 associated with each process station 160A-160F. For example, the process station 160A has a corresponding array of subsystems 261A-261D to be cooled by the upper fluid flow network 263. In the depicted embodiment, only subsystems 261A and 261B are shown and are only labeled for process station 160A. The array of subsystems 261A-261D may include various process components associated with each process station 160A-160F. For example, subsystem 261A may include a process source (e.g., a target), 261B may include a process adapter, 261C may include a turbo motor or turbomolecular pump (e.g., the vacuum pump 165 in FIG. 1), and 261D may include a pedestal such as a pedestal configured to raise and lower the substrate discussed in relation to FIG. 1 or a pedestal heater. In one embodiment, the subsystems 261A-261C are connected to the upper fluid flow network 263 and are cooled by the inlet cooling fluid. For example, each subsystem 261A-261C is disposed between and fluidly connected to the inlet manifold 372 and the outlet manifold 373 of each cooling assembly 270A-270F as described in relation to FIGS. 3A-4B. In the depicted embodiment, the subsystem 261D is fluidly connected to the inlet manifold 372 but not the outlet manifold 373, as described in relation to FIG. 4B. In some embodiments, the subsystem 261D may connect to the outlet manifold. The array of subsystems 261A-261D are further shown and described in relation to FIG. 4B.

The fluid delivery system 200 further includes a lower fluid flow network 264 configured to flow an input cooling fluid (not shown) to a second plurality of subsystems 262 of the processing chamber 150. The lower fluid flow network 264 includes an input manifold 266 and an output manifold 268. The input manifold 266 may include an input weldment 267 configured to accept the flow of the input cooling fluid into the lower fluid flow network 264. The input manifold 266 is configured to divert the flow of the input cooling fluid to the second plurality of subsystems 262, which comprises subsystems 262A-262E to be cooled. For example, subsystem 262A may include a mainframe (e.g., the processing chamber 150), 262B and 262C may each include a DC power supply (DCPS), 262D may include a spindle motor configured to rotate the support arm 108 described in relation to FIG. 1 and/or a ferrofluid seal of the spindle motor, and 262E may include a turbo motor or turbomolecular pump. The output manifold 268 may include an output weldment 269 configured to evacuate the input cooling fluid from the lower fluid flow network 264 after cooling the second plurality of subsystems 262.

In the depicted embodiment, the inlet cooling fluid is different from the input cooling fluid. In some embodiments, the inlet cooling fluid and the input cooling fluid may be the same type of fluid. In some embodiments, the inlet cooling fluid is de-ionized (DI) water. In some embodiments, the input cooling fluid may be reverse osmosis (RO) water or water with additives to prevent bacteria, corrosion, and the like.

In some embodiments, the first and second plurality of subsystems 260 and 262, respectively, may comprise more or less subsystems, including subsystems not discussed.

### Upper Fluid Flow Network Configuration Examples

FIGS. 3A and 3B depict an isometric view of the upper fluid flow network 263, according to one or more embodiments. In particular, FIG. 3A shows inlet components of the upper fluid flow network 263 and FIG. 3B shows outlet components of the upper fluid flow network 263.

As shown in FIG. 3A, the upper fluid flow network 263 comprises a supply weldment 340 fluidly connected to an inlet weldment 342. In the depicted embodiment, the inlet weldment 342 comprises a plurality of inlet weldment 342 pieces, shown as two inlet weldment 342 pieces, connected by a flex line 341. Each cooling assembly 270A-270F of the upper fluid flow network 263 includes an inlet manifold 372, and the inlet weldment 342 is fluidly connected to each inlet manifold 372 of each cooling assembly 270A-270F. The inlet manifold 372 connects to the first plurality of subsystems 260 as described in relation to FIG. 4B.

In the depicted embodiment, the inlet weldment 342 further comprises a plurality of inlet weldment valves 343. Each inlet weldment valve 343A-343F of the inlet weldment valves 343 fluidly connects the inlet weldment 342 to each inlet manifold 372 of each cooling assembly 270A-270F through an inlet connection line 382, which may be a flex line. The inlet weldment valves 343 may each be used to stop the flow of the inlet cooling fluid to the first plurality of subsystems 260. For example, an inlet weldment valve 343A may be used to stop flow of the inlet cooling fluid to the inlet manifold 372 of the cooling assembly 270A.

In some embodiments, the supply weldment 340 connects to the inlet weldment 342 through a camlock connection. The camlock connection may be a 2-inch connection. In some embodiments, the supply weldment is configured to connect to a facility connection through a camlock connection. The camlock connection may be the same size as the camlock connection between the supply and inlet weldments. For example, the cam lock connection may be a 2-inch connection.

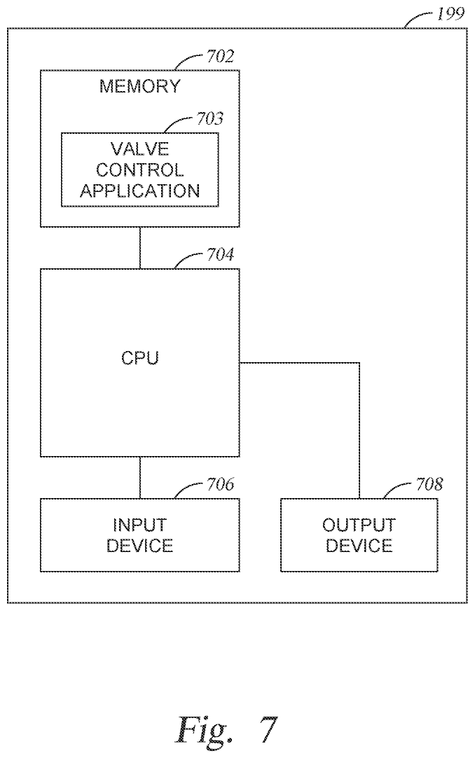

In some embodiments, the inlet weldment valves 343 may comprise a globe valve. In some embodiments, the inlet weldment valves 343 may be electronically actuated by the system controller 199 as discussed in relation to FIG. 7. In some embodiments, the inlet weldment valves 343 may be actuated or set by hand. A valve position sensor or a flow sensor may be used to detect a position of the inlet weldment valves 343 (e.g., open, closed, and partially open).

In some embodiments, a length of the flex line 341 may between about 40.9 inches and about 45.2 inches.

As shown in FIG. 3B, the upper fluid flow network 263 comprises at least one collection weldment 348 fluidly connected to an outlet weldment 346. In the depicted embodiment, the outlet weldment 346 comprises a plurality of outlet weldment 346 pieces shown as two outlet weldments 346 pieces, where each outlet weldment 346 piece of the plurality of outlet weldment 346 pieces connects to a collection weldment 348. The collection weldments 348 may comprise a flex line, similar to the flex line 341. Each cooling assembly 270A-270F of the upper fluid flow network 263 includes an outlet manifold 373, and the outlet weldment 346 is fluidly connected to each outlet manifold 373 of each cooling assembly 270A-270F. The outlet manifold 373 connects to the first plurality of subsystems 260 as described in relation to FIGS. 4A and 4B, where FIG. 4B refers to the array of subsystems 261.

In the depicted embodiment, each outlet weldment 346 comprises a plurality of outlet weldment connectors 347. Each outlet weldment connector 347A-347L of the outlet weldment connectors 347 fluidly connects each cooling assembly 270A-270F to the outlet weldments 346 through an outlet connection line 383, which may be a flex line, or an outlet cooling line 477D as described in relation to FIG. 4B. The outlet weldment connectors 347A-347L may be different types of connectors. For example, as shown in FIG. 3B, the outlet weldment connectors 347A-347F are different from the outlet weldment connectors 347G-347L. In some embodiments, at least one of the outlet weldment connectors 347A-347L may be a valve or a quick release connector. The outlet weldment connectors 347A-347L are further discussed in relation to FIGS. 4A and 4B.

In some embodiments, a length of the at least one collection weldment 348 may between about 27.5 inches and about 33.2 inches.

In some embodiments, the supply, inlet, outlet, and collection weldments 340, 342, 346, and 348, respectively, may be configured differently. For example, the inlet weldment 342 may be one piece such that a flex line 341 is not used. The supply weldment 340 may comprise more than one piece similar to the depicted configuration of the collection weldments 348. There may be only one outlet weldment 346 and/or only one collection weldment 348.

In some embodiments, the upper fluid flow network 263 may be configured differently. For example, the inlet and outlet connection lines 382 and 383 may be located between the inlet weldment 342 and each inlet weldment valve 343A-343F. For example, the inlet weldment valves 343 may be part of the inlet manifolds 372.

Although the flex line 341, collection weldments 348, and inlet and outlet connection lines 382 and 383 are shown as flex line in FIGS. 3A and 3B, each may be made of a rigid material in other embodiments. Flex line may comprise a flexible line or hose. For example, flex line may include a rubber-like material, braided hose such as a stainless steel braided hose, or a corrugated hose and the like.

Although the term “weldment” is used, it is not meant to limit the construction or configuration or any component. For example, the inlet weldment 342 may comprise pieces, for example, threaded together instead of welded. The inlet weldment 342 may also comprise one or more pieces that are bent to the desired shape.

Flow Configuration for an Upper Fluid Flow Network

FIGS. 4A and 4B depict a fluid schematic of the upper fluid flow network 263 for cooling a processing chamber, such as the processing chamber 150 discussed in relation to FIG. 1, according to one or more embodiments. In particular, FIG. 4A shows the upper fluid flow network 263 and FIG. 4B shows the connections between the inlet manifold 372 and the outlet manifold 373 of the cooling assembly 270A.

Referring to FIG. 4A, the inlet cooling fluid enters the upper fluid flow network 263 through the supply weldment 340 and flows through the inlet weldment 342, which directs the inlet cooling fluid to the inlet manifolds 372. The inlet weldment valves 343, if open, allow the inlet cooling fluid to flow to the inlet manifolds 372. As shown in FIG. 4A, the connections between the inlet manifold 372 and the outlet manifold 373 and the outlet weldments 346 are shown as a dashed line to indicate the connection is a simplified view of the actual connections. For example, the inlet manifolds 372 disperse the inlet cooling fluid to cool each array of subsystems 261, collectively referred to as the first plurality of subsystems 260, as discussed in relation to FIG. 4B. The inlet cooling fluid flows to the outlet manifolds 373 and through the outlet weldment connectors 347A-347F to one of two outlet weldments 346. The inlet cooling fluid may also flow to the outlet weldment connectors 347G-347L without flowing through the outlet manifolds 373 as further discussed in relation to FIG. 4B. Each outlet weldment 346 evacuates the inlet cooling fluid from the upper fluid flow network 263 through the collection weldments 348.

Although several components are discussed in relation to FIG. 4A, the upper fluid flow network 263 may include additional components. For example, the upper fluid flow network 263 may include an air inlet line configured to blow out the inlet cooling fluid from the upper fluid flow network 263 as discussed in relation to FIG. 4B.

Referring to FIG. 4B, a fluid flow path for the cooling assembly 270A is shown. The inlet weldment 342 includes an inlet weldment pressure regulator 436 disposed before the inlet weldment valve 343. The inlet weldment pressure regulator 436 controls the pressure of the inlet cooling fluid entering the inlet manifold 372.

The inlet manifold 372 directs the inlet cooling fluid to the array of subsystems 261 to be cooled through a plurality of inlet manifold cooling lines 476. Each inlet manifold cooling line 476A-476D of the inlet manifold cooling lines 476 fluidly connects the inlet manifold 372 to a subsystem 261A-261D of the array of subsystems 261. For example, the inlet manifold cooling line 476A connects to the subsystem 261A. The cooling assembly 270A may further include a plurality of inlet manifold valves 438. Each inlet manifold valve 438A-438D fluidly connects to each inlet manifold cooling line 476A-476D and may start or stop flow of the inlet cooling fluid to each subsystem 261A-261D. For example, the inlet manifold valve 438A may be used to stop flow of the inlet cooling fluid to the subsystem 261A while the inlet cooling fluid flows to the subsystems 261B-261D.

The inlet cooling fluid flows through the array of subsystems 261, through a plurality of outlet manifold cooling lines 477A-477C, and to the outlet manifold 373. Each outlet manifold cooling line 477A-477C fluidly connects each subsystem 261A-261C of the array of subsystems 261 to the outlet manifold 373. The outlet manifold 373 is fluidly connected to the outlet weldment 346 through the outlet weldment connector 347A and outlet connection line 383. An outlet cooling line 477D fluidly connects the subsystem 261D to the outlet weldment 346. In the depicted embodiment, the outlet cooling line 477D of the cooling assembly 270A connects to the outlet weldment 346 through the outlet weldment connector 347G.

The cooling assembly 270A includes a first plurality of flow restrictors 486. In the depicted embodiment, the first plurality of flow restrictors 486 are a plurality of outlet flow restrictors 486. Each outlet flow restrictor 486A-486C of the outlet flow restrictors 486 is fluidly connected to each subsystem 261A-261C of the array of subsystems 261 and to a respective outlet manifold 373. An outlet flow restrictor 486D is fluidly connected to the subsystem 261D and the outlet weldment 346. The outlet flow restrictors 486 beneficially provide a constant flow rate of the inlet cooling fluid through each subsystem 261A-261D. For example, the pressure of the inlet cooling fluid may vary at each inlet manifold 372 because each inlet manifold 372 is at a different downstream distance from the supply weldment 340. The pressure inside each of the cooling lines 476A-476D and 477A-477D may vary because each of the cooling lines 476A-476D and 477A-477D may have a different inner diameter or be a different length. The different pressures may result in different flow rates, which may affect the cooling of the array of subsystems 261.

The outlet flow restrictors 486 provide a constant flow rate for a range of different pressures. For example, each outlet flow restrictor 486A-486D may provide a constant flow rate between a first predetermined pressure and a second predetermined pressure. Thus, each outlet flow restrictor 486A-486D may be configured to maintain the inlet cooling fluid flow through each subsystem 261A-261D at a desired flow rate for a given pressure range, which beneficially accounts for a reduced inner diameter of the cooling lines 476 and 477A-477D from accumulated sediment. For example, the outlet flow restrictor 486A may be configured to maintain a predetermined mass flow rate of inlet cooling fluid through the subsystem 261A for different pressures. The predetermined mass flow rate may be chosen to provide a desired cooling rate of the subsystem 261A between the first predetermined pressure and the second predetermined pressure. The outlet flow restrictors 486 may be selected based on inlet cooling fluid velocity requirements and/or a pressure head.

An air inlet line 454 may also connect to the inlet connection line 382. The air inlet line 454 may be used to purge the cooling assembly 270A of the inlet cooling fluid, such as when a cooling operation is complete or when the processing chamber is undergoing maintenance. The air inlet line 454 may include an air inlet pressure regulator 456 and an inlet air valve 458. In some embodiments, the pressurized air in the air inlet line may be about 80 psi before the air inlet pressure regulator 456. In some embodiments, the air inlet pressure regulator 456 may control the air pressure to be between about 0-40 psi. In some embodiments, the inlet air valve 458 may be a blow out valve that releases the pressurized air into the cooling assembly 270A of the upper fluid flow network 263 when the inlet cooling fluid is purged from the cooling assembly 270A. For example, the inlet weldment valve 343 is shut to prevent cooling fluid from entering. The inlet air valve 458 is then open to allow the air to flow through the cooling assembly 270A and purge the inlet cooling fluid from the cooling assembly 270A. The cooling assembly 270A may be purged for several reasons including maintenance or scheduled down time.

Although the fluid flow path is discussed in relation to the cooling assembly 270A, the fluid flow path may be the same for the cooling assemblies 270A-270F.

In some embodiments, each inlet manifold cooling line 476A-476D of a cooling assembly 270A-270D of the plurality of cooling assemblies 270 is roughly equal in length to a corresponding inlet manifold cooling line in a different cooling assembly of the plurality of cooling assemblies 270. For example, the inlet manifold cooling line 476A of the cooling assembly 270A may be the same length as the inlet manifold cooling line 476A of the cooling assembly 270B. In some embodiments, each inlet manifold cooling line 476A-476D of a cooling assembly 270A-270D of the plurality of cooling assemblies 270 is roughly equal in diameter to a corresponding inlet manifold cooling line in a different cooling assembly of the plurality of cooling assemblies. For example, the inlet manifold cooling lines 476A of the cooling assemblies 270A and 270B may have the same inner and/or outer diameter.

In some embodiments, the length and/or diameter of each inlet manifold cooling line 476A-476D may be selected based on characteristics of each cooling assembly 270A-270F. For example, as shown in FIG. 2, the cooling assemblies 270C and 270D are a further downstream distance from the supply weldment 340 than the cooling assemblies 270A and 270F. Thus, the cooling assemblies 270C and 270D may have a lower pressure at the inlet manifold 372 than the cooling assemblies 270A and 270F. To compensate, different lengths and/or diameters may be used for the cooling lines 476 for the cooling assemblies 270C and 270D than the cooling assemblies 270A and 270F to achieve the same flow rates. As shown in FIG. 1, the processing chamber 150 near the cooling assemblies 270A and 270F connects to the intermediate robot chamber 180, which functions as a heat sink. Thus, the cooling assemblies 270A and 270F may not be required to cool at the same rate as the cooling assemblies 270C and 270D, which are not near a heat sink. Selecting the cooling lines 476 based on the characteristics of each cooling assembly 270A-270F beneficially provides similar flow conditions for all the cooling assemblies 270, which allows similar outlet flow restrictors 486 to be used for each cooling assembly 270A-270F.

In some embodiments, each outlet flow restrictor 486A-486D may be one of an inline flow restrictor, a capillary insert flow restrictor, a fitting connector flow restrictor combo, or an integral flow restrictor. In some embodiments, each outlet flow restrictor 486A-486D may maintain a constant flow using movable elements, such as springs and plates, to account for variations in input pressures and maintain a constant output flow rate. In some embodiments, each outlet flow restrictor 486A-486D is selected to maintain a predetermined flow rate based on the model flow restrictor selected. For example, different models of flow restrictors may provide different flow rates. Thus, the desired flow rate may be maintained by selecting a model flow restrictor, which beneficially avoids the need to provide a separate controller or power source to control the flow rate.

In some embodiments, the outlet manifold 373 may comprise the outlet flow restrictor 486 of each cooling assembly 270A-270F.

In some embodiments, the first plurality of flow restrictors 486 may include a plurality of inlet flow restrictors (not shown). Each inlet flow restrictor of the inlet flow restrictors is fluidly connected to an inlet manifold 372 and to each subsystem 261A-261D of the array of subsystems 261. The inlet flow restrictors may function similarly to the outlet flow restrictors 486 previously described. In some embodiments, the first plurality of flow restrictors 486 may only include inlet flow restrictors.

In some embodiments, the inlet weldment pressure regulator 436 may be disposed after the valve 343. In some embodiments, the inlet weldment pressure regulator 436 and the valve 343 may be the same component such that the inlet weldment pressure regulator 436 controls the valve 343 to adjust the input pressure.

In some embodiments, the inlet manifold valves 438 and the inlet air valve 458 may be electronically actuated by the system controller 199 as discussed in relation to FIG. 7. In some embodiments, the valves 438 and 458 may be actuated or set by hand. A valve position sensor or a flow sensor may be used to detect a position of the valves 438 and 458 (e.g., open, closed, and partially open).

In some embodiments, the upper fluid flow network 263 may include additional components not discussed. For example, the air line or the fluid line may include a filter to filter out contaminants such as air or water or ensure a predetermined purity level.

Although DI water and air are discussed, other sources may be used. For example, water with additives, RO water, glycol, or another cooling fluid may be used instead of DI water. Other gas such as nitrogen or argon may be used instead of air.

Flow Configuration for a Lower Fluid Flow Network

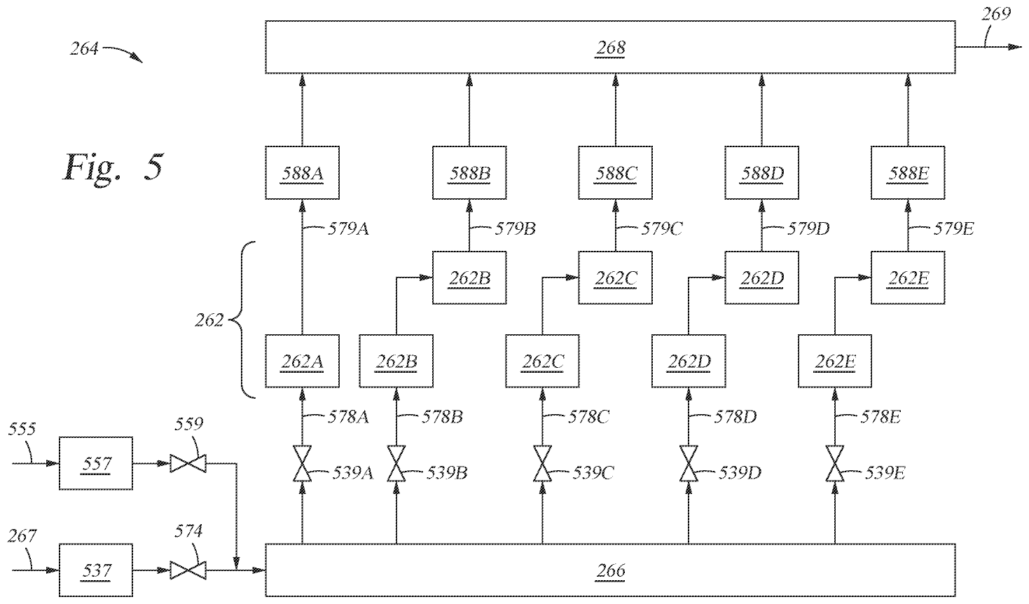

FIG. 5 depicts a fluid schematic of a lower fluid flow network 264 for cooling a substrate processing system 100, according to one or more embodiments. A fluid flow path depicted of the lower fluid flow network 264 is functionally similar to the fluid flow path for the cooling assembly 270A as discussed in relation to FIG. 4B, except as otherwise noted. Thus, features of FIG. 4B may be discussed without express reference to FIG. 4B.

The input weldment 267 includes an input weldment pressure regulator 537 disposed before an input weldment valve 574, which function similar to the inlet weldment pressure regulator 436 and the inlet weldment valve 343. The components and connections between the input manifold 266 and the output manifold 268 are similar to the components and connections between the inlet manifold 372 and the outlet manifold 373. As depicted, the lower fluid flow network 264 includes a plurality of input manifold cooling lines 578 and a plurality of output manifold cooling lines 579. Each input manifold cooling line 578A-578E of the input manifold cooling lines 578 fluidly connects the input manifold 266 to the subsystems 262A-262E. Each output manifold cooling line 579A-579E of the output manifold cooling lines 579 fluidly connects the subsystems 262A-262E to the output manifold 268. The lower fluid flow network 264 includes a plurality of input manifold valves 539 and a second plurality of flow restrictors 588. In the depicted embodiment, the second plurality of flow restrictors 588 are a plurality of output flow restrictors 588. Each input manifold valve 539A-539E is similar to the inlet manifold valves 438 and each output flow restrictor 588A-588E is similar to the outlet flow restrictors 486. For example, each output flow restrictor 588A-588E of the output flow restrictors 588 may be fluidly connected to each subsystem 262A-262E of the second plurality of subsystems 262 and the output manifold 268.

In the depicted embodiment, the subsystems 262B are connected in series. The subsystems 262C, 262D, and 262E are each similarly connected in series. Thus, the input cooling fluid flows through these subsystems in series before flowing through the output manifold cooling lines 579.

The input cooling fluid flows through the input weldment 267 and to the input manifold 266, which disperses the input cooling fluid to the second plurality of subsystems 262 through the plurality of input manifold cooling lines 578. The input cooling fluid flows out the second plurality of subsystems 262 and to the output manifold 268 and through the plurality of output manifold cooling lines 579. The input cooling fluid is evacuated from the lower fluid flow network 264 through the output weldment 269.

An air input line 555 may connect to the input weldment 267. The air input line 555 may include an air input pressure regulator 557 and an input air valve 559. The air input line 555, air input pressure regulator 557, and input air valve 559 are functionally similar to the air inlet line 454, air inlet pressure regulator 456, and inlet air valve 458, respectively.

In the depicted embodiment, the input and output manifold cooling lines 578 and 579 are similar to the input and output manifold cooling lines 578 and 579. For example, a length and a diameter of each input and output manifold cooling lines 578A-578E and 579A-579E may be sized to achieve a desired flow rate through the subsystems 262A-262E.

In some embodiments, the second plurality of flow restrictors 588 may include a plurality of input flow restrictors (not shown). Each input flow restrictor of the input flow restrictors is fluidly connected to the input manifold 266 and to each subsystem 262A-262E of the second plurality of subsystems 262. The input flow restrictors may function similarly to the output flow restrictors 588 previously described. In some embodiments, the second plurality of flow restrictors 588 may only include input flow restrictors.

In some embodiments, the input manifold valves 539, the input air valve 559, and the input weldment valves 574 and the inlet air valves 458 may be electronically actuated by the system controller 199 as discussed in relation to FIG. 7. In some embodiments, the valves 539, 559, and 574 may be actuated or set by hand. A valve position sensor or a flow sensor may be used to detect a position of the valves 438 and 458 (e.g., open, closed, and partially open).

In some embodiments, the inlet manifolds 372 may be referred to as a first plurality of manifolds. The outlet manifolds 373 may be referred to as a second plurality of manifolds. In some embodiments, the supply and inlet weldments 340 and 342 may be referred to as a first subset of the first plurality of cooling lines. The plurality of inlet manifold cooling lines 476 may be referred to as a second subset of the first plurality of cooling lines. The plurality of outlet manifold cooling lines 477A-477C may be referred to as a third subset of the first plurality of cooling lines. The outlet and collection weldments 346 and 348 may be referred to as a fourth subset of the first plurality of cooling lines.

In some embodiments, the input manifold 266 may be referred to as a first manifold. The output manifold 268 may be referred to as a second manifold. In some embodiments, the input weldment 267 may be referred to as a fifth subset of the second plurality of cooling lines. The plurality of input manifold cooling lines 578 may be referred to as a sixth subset of the second plurality of cooling lines. The plurality of output manifold cooling lines 579 may be referred to as a seventh subset of the second plurality of cooling lines.

### Example Methods of Cooling a Substrate Processing System

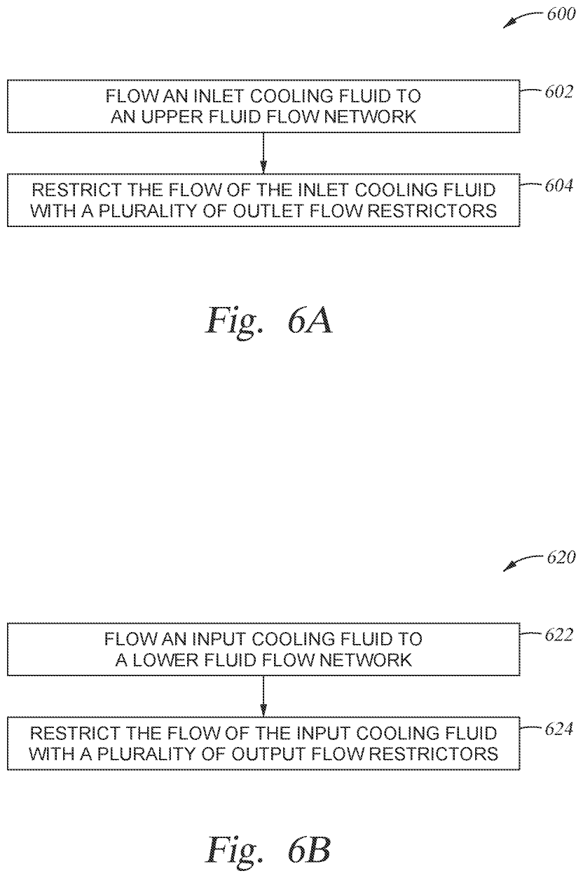

FIGS. 6A and 6B depict example methods of cooling the substrate processing system 100, according to another example of the present disclosure.

Referring to FIG. 6A, a method 600 begins at operation 602 with flowing an inlet cooling fluid through an upper fluid flow network, e.g., upper fluid flow network 263.

Method 600 then proceeds to operation 604 with restricting the flow of the inlet cooling fluid with a plurality of outlet flow restrictors, such as outlet flow restrictors 486.

Referring to FIG. 6B, a method 620 begins at operation 622 with flowing an input cooling fluid through a lower fluid flow network, such as the lower fluid flow network 264.

Method 620 then proceeds to operation 624 with restricting the flow of the input cooling fluid with a plurality of output flow restrictors, such as output flow restrictors 588.

Note that FIGS. 6A and 6B are just examples of a method, and other methods including fewer, additional, or alternative operations are possible consistent with this disclosure.

### Controller for Upper Fluid Flow Network Examples

FIG. 7 depicts a functional block diagram of one example of the system controller 199 for cooling a substrate processing chamber, such as processing chamber 150, according to embodiments described herein. The system controller 199 includes a processor 704 (e.g., a central processing unit (CPU)) in data communication with a memory 702, an input device 706, and an output device 708. In some embodiments, the processor 704 is further in data communication with an optional network interface card (not shown). Although described separately, it is to be appreciated that functional blocks described with respect to the system controller 199 need not be separate structural elements. For example, the processor 704 and memory 702 is embodied in a single chip. The processor 704 can be a general purpose processor, a digital signal processor (“DSP”), an application specific integrated circuit (“ASIC”), a field programmable gate array (“FPGA”) or other programmable logic device, discrete gate or transistor logic, discrete hardware components, or any suitable combination thereof designed to perform the functions described herein. A processor may also be implemented as a combination of computing devices, e.g., a combination of a DSP and a microprocessor, a plurality of microprocessors, one or more microprocessors in conjunction with a DSP core, or any other such configuration.

The processor 704 can be coupled, via one or more buses, to read information from or write information to memory 702. The processor 704 may additionally, or in the alternative, contain memory, such as processor registers. The memory 702 can include processor cache, including a multi-level hierarchical cache in which different levels have different capacities and access speeds. The memory 702 can also include random access memory (RAM), other volatile storage devices, or non-volatile storage devices. The storage can include hard drives, flash memory, etc. The memory 702 can also include a valve control application 703, which is used to control any of the inlet weldment valves 343, the inlet manifold valves 438, the inlet air valve 458, input manifold valves 539, the input air valve 559, and the input weldment valves 574. Valve control application 703 may be code that can be executed by the processor 704. In various instances, the memory 702 is referred to as a computer-readable storage medium. The computer-readable storage medium is a non-transitory device capable of storing information, and is distinguishable from computer-readable transmission media such as electronic transitory signals capable of carrying information from one location to another. The non-transitory computer readable medium includes computer-executable instructions that, when executed by a processing system, cause the processing system to perform a method, as described in relation to FIGS. 6A and 6B, including flowing an inlet cooling fluid through an upper fluid flow network and flowing an input cooling fluid through a lower fluid flow network. Computer-readable medium as described herein may generally refer to a computer-readable storage medium or computer-readable transmission medium.

The processor 704 also may be coupled to an input device 706 and an output device 708 for, respectively, receiving input from and providing output to a user of the system controller 199. Suitable input devices include, but are not limited to, a keyboard, buttons, keys, switches, a pointing device, a mouse, a joystick, a remote control, an infrared detector, a bar code reader, a scanner, a video camera (possibly coupled with video processing software to, e.g., detect hand gestures or facial gestures), a motion detector, or a microphone (possibly coupled to audio processing software to, e.g., detect voice commands). The input device 706 includes a valve position sensor or flow rate sensor as discussed in relation to FIGS. 3A, 4B, and 5. Suitable output devices include, but are not limited to, the inlet weldment valves 343, the inlet manifold valves 438, the inlet air valve 458, input manifold valves 539, the input air valve 559, and the input weldment valves 574 as discussed in relation to FIGS. 3A, 4B, and 5 as well as visual output devices, including displays and printers, audio output devices, including speakers, headphones, earphones, and alarms, additive manufacturing machines, and haptic output devices. As discussed in relation to FIGS. 4A-4D, the output device 708 includes various electrical components that are configured to drive and control a mechanism or motor that is used to control the power supplied to the inlet weldment valves 343, the inlet manifold valves 438, the inlet air valve 458, input manifold valves 539, the input air valve 559, and the input weldment valves 574.

Aspects of the present disclosure been described above with reference to specific embodiments. Persons skilled in the art, however, will understand that various modifications and changes may be made thereto without departing from the broader spirit and scope of the invention as set forth in the appended claims. The foregoing description and drawings are, accordingly, to be regarded in an illustrative rather than a restrictive sense.

What is claimed is:

1. A substrate processing system, comprising:
a processing chamber comprising an array of process stations surrounding a central axis; and
an upper fluid flow network configured to flow an inlet cooling fluid to a first plurality of subsystems of the processing chamber, comprising:
a plurality of cooling assemblies, wherein each cooling assembly of the plurality of cooling assemblies is associated with a process station of the array of process stations and each cooling assembly comprises:
an inlet manifold and a plurality of inlet manifold cooling lines, wherein each inlet manifold cooling line of the plurality of inlet manifold cooling lines fluidly connects the inlet manifold to a subsystem of the first plurality of subsystems,
an outlet manifold and a plurality of outlet manifold cooling lines, wherein each outlet manifold cooling line of the plurality of outlet manifold cooling lines fluidly connects each subsystem of the first plurality of subsystems to the outlet manifold, and
an outlet flow restrictor fluidly connected to each subsystem of the first plurality of subsystems and to the outlet manifold,
a supply weldment fluidly connected to an inlet weldment, wherein the inlet weldment is fluidly connected to each inlet manifold of each cooling assembly; and
at least one collection weldment fluidly connected to an outlet weldment, wherein the outlet weldment is fluidly connected to each outlet manifold of each cooling assembly.

2. The substrate processing system of claim 1, further comprising:
a lower fluid flow network configured to flow an input cooling fluid to a second plurality of subsystems of the processing chamber, comprising:
an input manifold and a plurality of input manifold cooling lines, wherein each input manifold cooling line of the plurality of input manifold cooling lines fluidly connects the input manifold to each subsystem of the second plurality of subsystems,
an output manifold and a plurality of output manifold cooling lines, wherein each output manifold cooling line of the plurality of output manifold cooling lines fluidly connects each subsystem of the second plurality of subsystems to the output manifold, and
a plurality of output flow restrictors, wherein each output flow restrictor of the plurality of output flow restrictors is fluidly connected to each subsystem of the second plurality of subsystems and the output manifold.

3. The substrate processing system of claim 2, wherein the outlet manifold comprises the outlet flow restrictor of each cooling assembly of the plurality of cooling assemblies.

4. The substrate processing system of claim 3, wherein the output manifold comprises each output flow restrictor of the plurality of output flow restrictors.

5. The substrate processing system of claim 2, wherein the outlet weldment comprises a plurality of outlet weldment pieces, wherein each outlet weldment piece of the plurality of outlet weldment pieces connects to a collection weldment.

6. The substrate processing system of claim 2, wherein the inlet cooling fluid is different from the input cooling fluid.

7. The substrate processing system of claim 2, wherein the second plurality of subsystems comprises at least one of the processing chamber, a DC power supply, a spindle motor, a ferrofluid seal of the spindle motor, a turbo motor, or a turbomolecular pump.

8. The substrate processing system of claim 1, wherein the at least one collection weldment comprises a flex line.

9. The substrate processing system of claim 1, wherein the supply weldment connects to the inlet weldment through a camlock connection.

10. The substrate processing system of claim 1, wherein the inlet weldment comprises a plurality of inlet weldment pieces connected by a flex line.

11. The substrate processing system of claim 1, wherein each inlet manifold cooling line of a cooling assembly of the plurality of cooling assemblies is roughly equal in length to a corresponding inlet manifold cooling line in a different cooling assembly of the plurality of cooling assemblies.

12. The substrate processing system of claim 1, wherein each inlet manifold cooling line of a cooling assembly of the plurality of cooling assemblies is roughly equal in diameter to a corresponding inlet manifold cooling line in a different cooling assembly of the plurality of cooling assemblies.

13. The substrate processing system of claim 1, wherein:
the inlet weldment further comprises a plurality of inlet weldment valves, and
each inlet weldment valve of the plurality of inlet weldment valves fluidly connects the inlet weldment to each inlet manifold of each cooling assembly.

14. The substrate processing system of claim 1, wherein the first plurality of subsystems comprises at least one of a process source, a process adapter, a turbo motor, a turbomolecular pump, or a pedestal.

15. The substrate processing system of claim 1, further comprising:
an outlet cooling line, wherein the outlet cooling line fluidly connects a subsystem of the processing chamber to the outlet weldment; and
an outlet flow restrictor fluidly connected to the subsystem and the outlet weldment.

16. A substrate processing system, comprising:
a cooling system configured to cool a first plurality of subsystems and a second plurality of subsystems of a processing chamber, wherein the cooling system comprises:
a first plurality of cooling lines, wherein:
a first subset of the first plurality of cooling lines connects to a first plurality of manifolds,
a second subset of the first plurality of cooling lines connects the first plurality of manifolds to the first plurality of subsystems of the processing chamber,
a third subset of the first plurality of cooling lines connects the first plurality of subsystems of the processing chamber to a second plurality of manifolds, and
a fourth subset of the first plurality of cooling lines connects to the second plurality of manifolds; and
a first plurality of flow restrictors connected to the second subset or the third subset of the first plurality of cooling lines, wherein each flow restrictor of the first plurality of flow restrictors connects to a respective cooling line of the second subset or the third subset of the first plurality of cooling lines.

17. The substrate processing system of claim 16, further comprising:
a second plurality of cooling lines, wherein:
a fifth subset of the second plurality of cooling lines connects to a first manifold;
a sixth subset of the second plurality of cooling lines connects the first manifold to the second plurality of subsystems of the processing chamber; and
a seventh subset of the second plurality of cooling lines connect the second plurality of subsystems of the processing chamber to a second manifold; and
a second plurality of flow restrictors connected to the sixth or the seventh subset of the second plurality of cooling lines, wherein each flow restrictor of the second plurality of flow restrictors connects to a respective cooling line of the sixth subset or the seventh subset of the second plurality of cooling lines.

18. A method for cooling a substrate processing system, comprising:
flowing an inlet cooling fluid through an upper fluid flow network, wherein the upper fluid flow network comprises:
a plurality of cooling assemblies, wherein each cooling assembly of the plurality of cooling assemblies is associated with a process station of a processing chamber and each cooling assembly comprises:
an inlet manifold and a plurality of inlet manifold cooling lines, wherein each inlet manifold cooling line of the plurality of inlet manifold cooling lines fluidly connects the inlet manifold to a subsystem of a first plurality of subsystems, and
an outlet manifold and a plurality of outlet manifold cooling lines, wherein each outlet manifold cooling line of the plurality of outlet manifold cooling lines fluidly connects the subsystem of the first plurality of subsystems to the outlet manifold,
a supply weldment fluidly connected to an inlet weldment, wherein the inlet weldment is fluidly connected to each inlet manifold of each cooling assembly; and
at least one collection weldment fluidly connected to an outlet weldment, wherein the outlet weldment is fluidly connected to each outlet manifold of each cooling assembly; and
restricting the flow of the inlet cooling fluid with a plurality of outlet flow restrictors, wherein each outlet flow restrictor of the plurality of outlet flow restrictors is fluidly connected to each subsystem of the first plurality of subsystems and an outlet manifold.

19. The method of claim 18, further comprising:
flowing an input cooling fluid through a lower fluid flow network, wherein the lower fluid flow network comprises:
an input manifold and a plurality of input manifold cooling lines, wherein each input manifold cooling line of the plurality of input manifold cooling lines fluidly connects the input manifold to a subsystem of a second plurality of subsystems, and
an output manifold and a plurality of output manifold cooling lines, wherein each output manifold cooling line of the plurality of output manifold cooling lines fluidly connects the subsystem of the second plurality of subsystems to the output manifold; and
restricting the flow of the input cooling fluid with a plurality of output flow restrictors, wherein each output flow restrictor of the plurality of outlet flow restrictors is fluidly connected to each subsystem of the second plurality of subsystems and the output manifold.

20. The method of claim 18, wherein each inlet manifold cooling line of a cooling assembly of the plurality of cooling assemblies is roughly equal in length to a corresponding inlet manifold cooling line in the other cooling assemblies of the plurality of cooling assemblies.
